(19) United States
(12) Patent Application Publication
(10) Pub. No.: US 2009/0101940 A1
(43) Pub. Date: Apr. 23, 2009

(54) DUAL GATE FET STRUCTURES FOR FLEXIBLE GATE ARRAY DESIGN METHODOLOGIES

(76) Inventors: Corey K. Barrows, Colchester, VT (US); Joseph A. Iadanza, Hinesburg, VT (US); Edward J. Nowak, Essex Jct., VT (US); Douglas W. Stout, Milton, VT (US)

Correspondence Address: IBM MICROELECTRONICS;INTELLECTUAL PROPERTY LAW, 1000 RIVER STREET, 972 E, ESSEX JUNCTION, VT, 05452, US

(21) Appl. No.: 11/874,957

(22) Filed: Oct. 19, 2007

(51) Int. Cl. H01L 29/76; H01L 21/82; G06F 17/50

(52) U.S. Cl. 257/204; 438/128; 438/283; 716/16; 716/17; 257/E29.226; 257/E21.602

(57) ABSTRACT

A gate array cell adapted for standard cell design methodology or programmable gate array that incorporates a dual gate FET device to offer a range of performance options within the same unit cell area. The conductivity and drive strength of the dual gate device may be selectively tuned through independent processing of manufacturing parameters to provide an asymmetric circuit response for the device or a symmetric response as dictated by the circuit application.

### FIELD OF THE INVENTION

The field of the invention is related to gate array circuit and design structures and methodologies, and more particularly to dual-gate FET structures with tunable performance characteristics for improved flexibility of embedded gate array circuit applications and topologies.

### BACKGROUND OF THE INVENTION

Over the past two decades, two basic design styles have dominated the field of mask programmable Application Specific Integrated Circuit (ASIC) design: standard cell (SC) and Gate Array (GA). The standard cell methodology creates a library of primitive logic devices as well as higher level circuit functions to facilitate ease of design through the elimination of repetitive physical layout and verification for commonly used logic functions. Standard cell methodology offers circuit designers great flexibility in circuit tuning within the ASIC library as well as the option of placing multiple performance levels or drive strengths of a circuit within the same unit cell area. Often referred to as a logic or macro cell, standard cell design methodology offers chip designers greater flexibility in meeting chip area and performance targets while enhancing chip functional capability through the availability of dense functional units or cores, including memory, microprocessors and other analog or digital functions.

A drawback to the standard cell design methodology is the requirement of longer design cycles and manufacturing times and therefore higher costs because all photolithographic mask levels of the integrated circuit (IC) are unique to a single design. In addition, design errors within standard cell ICs can be expensive, requiring redesign of the IC from the transistor definition levels upward. Conversely, gate array design constrains the circuit designer to predetermined transistor sizes, physical layout and count within the base logic cell, which is used as a building block for larger designs. In this regard, gate array design cannot support a wide range of performance levels for a given circuit within the same chip floor plan area. Gate array design also eliminates the potential of offering dense or complex functions such as dedicated memory, microprocessors or analog functions. However, gate array design allows the chip development team to speed development and, in some cases, eliminate manufacturing related delays at a reduced cost compared to standard cell design, since many of the mask levels of the IC are common among many designs and are preprocessed. Due to preprocessing of wafers through the transistor definition masks, design errors can be corrected more quickly and at lower cost, as only the interconnect or Back End Of the Line (BEOL) levels of the IC need be rebuilt.

Gate array also offers IC manufacturing uniformity advantages over its standard cell counterpart due to the repetition of common transistor structures throughout the design. As a result, analog designers often use “gate array” like structures deep within their circuit physical structures to improve matching of transistor parametric characteristics. Over the past two decades, ASIC design methodologies have been developed to produce standard cell ICs while filling any open space within the IC with gate array background or filler cells having predetermined transistor sizes and layout. The gate array cells are used to modify or repair standard cell based functions should any logic bugs be found after manufacture. Transistor availability provided by the gate array background allows repair of the IC using only BEOL levels, reducing cost and time, however, because of limitations on performance and area associated with the gate array topology, repairs capable of fitting into available gate array background cells and meeting performance requirements may not be feasible. A more flexible topology and methodology for its use is needed and would benefit not only chip level designers, but digital and analog circuit designers as well. We disclose novel FET structures to improve gate array topology capability toward this end.

FIG. 1 depicts a single exemplary gate array background cell 100 of known design and topology according to the prior art. In a gate array (GA) centric design, a uniform distribution of these cells would be placed and made available for personalized wiring of the transistors. In SCGA IC designs, die area not consumed by standard cells (SC) is filled with background GA cells so that additional transistors are available on the die if needed. The gate array background cell consists of two transistor regions, PFET region 101 and NFET region 102. Within each region, two transistors, defined by the intersection of the polysilicon gate 103 and diffusion regions 104, 105 are shown. The component of the diffusion region where the polysilicon gate does not intersect defines the source and drain regions of the transistors and appears on the right side, center and left side of each diffusion region 104 and 105. As multiple gate array background cells are placed, the left and right diffusion areas abut one another such that spacing from transistor to transistor is uniform. In typical gate arrays, all PFETs will be of one predefined width and length and all NFETs will be of one predefined width and length. The NFET and PFET width (W) and length (L) dimensions need not be equal and more typically are not identically sized. The physical layout of the cell is structured to plan for contact of the polysilicon gates outside the diffusion areas as well as contact of the diffusion region between each gate. Such accommodations reduce the number of transistors that may be physically placed within the cell as well as fixing their size and wireability.

FIGS. 2a and 2b illustrates the cross sectional view through the NFET and PFET device regions respectively of the prior art gate array background cell shown in FIG. 1. Both the NFET 201 and PFET 202 sections show diffusion to the extreme right and left of the cell as well as at the center of the cell. Each diffusion region 203, 204 is adequate in width for placing contacts to the diffusion to facilitate interconnect, if needed. Two regions of thin oxide 205 (crosshatched) topped with polysilicon gates 206, 207 form the transistor gates. Polysilicon in NFET regions is N doped and polysilicon in PFET regions is P doped, setting the work functions for each transistor type. The substrate region of the NFET and PFET sections is doped opposite to that of the source/drain diffusions. Application of a gate voltage results in a field being generated between the gate and bulk node/substrate/well of the transistor (bulk connection contact not shown in cell). The resulting field may either accumulate charge in the channel region under the gate, cutting off the diffusions to the right and left of the gate/oxide region from each other, or deplete the native charge from the bulk/substrate/well underneath the gate region, inverting the semiconductor type and forming a connection between the source and drain diffusions. FIG. 2c illustrates the cross sectional view through isolation area 208 of the cell where polysilicon runs over thick oxide. Contact of the polysilicon from metallurgy above may be made in the isolation regions.

FIGS. 3a and 3b illustrate the schematic 300 and physical layout 301 of a typical 2-input AND logic function built in a CMOS technology and implemented with a pair of prior art gate array background cells placed next to each other. FIG. 3b details a physical view of the gate array diffusion and transistor layout coupled with interconnect routing to indicate gate and diffusion connections to match the schematic. Comparing the physical representation to the schematic representation, it is apparent the physical layout consumes two full gate array background cells (8 FETs) even though the schematic representation only contains 6 FETs. This loss in efficiency is due both to the cell definition of two PFETs and two NFETs and to necessary isolation requirements between the source and drain diffusions within the gate array to implement the function. At some points within the layout, it is necessary to guarantee separation of nodes, requiring that the transistor between the nodes be tied off in a manner which guarantees the transistor will remain off. As can be noted in the schematic of FIG. 3a, all PFET instances in the schematic are identical to one another, having the same drive strength as is dictated by the gate array background and in a similar manner all NFET instances in the schematic are identical to one another. (W/L ratios are uniform.) Improving the drive strength of one or more NFET or PFET instances in the circuit would require placing multiple transistors in parallel. As this occurs, the number of cells required to physically implement the circuit grows, and strengthening of each FET is quantized into even multiples of the base NFET and PFET devices. As the schematic for the circuit grows, the physical implementation may grow at a rate faster than that of the schematic due to the need to tie certain transistors off to provide source/drain isolation, thus, the flexibility and efficiency of gate array circuits are severely limited.

As illustrated in FIG. 4, a number of different current source and diode-connected load circuit topologies are possible in prior art gate array ICs or prior art gate array style layouts within analog regions of current technology ICs. Both NFET and PFET examples are provided in schematic and physical form. Again, the size of these structures is quantized by strength-related parameters such as Vt, L and W of the FET in the gate array background—all of which limit design flexibility. As with the logic circuit example of FIG. 3, a physical device count penalty is incurred each time adjacent diffusion areas require separation from one another, as the gate between the diffusions must be tied down and made unavailable for use within the circuit.

Recent advances in semiconductor manufacturing processing have resulted in the creation of a dual gate FET device, which is illustrated in FIG. 5. While there are a number of different physical implementations of a dual gate FET, the basic structure consists of a channel region 506 of thickness, Tₛᵢ sandwiched between two gate regions 501, 502 defined by polysilicon over oxide with source and drain diffusions 503, 504 abutting the channel region.

With the requirement that channel region 506 of the dual gate device is thick enough and doped in a manner to support two distinct channels through the channel region, the dual gate FET may be thought of as two independent FETs built in parallel between the source and drain of the device. While the length and width of the two “parallel” devices is linked, the parametric behavior of the devices need not be. The structure and behavior of a symmetric dual gate FET is illustrated in FIG. 6. Symmetric dual gate FETs are characterized by equivalent oxide thickness and gate work functions for the front and back side FETs along with symmetrical channel doping. Given sufficient thickness, Tₛᵢ (i.e. greater than the quantum limit of approximately 4 nm), two distinct channels of equal strength and conductivity are possible through the channel region 506 of the dual gate FET as shown in the graph of electron density vs. position in body 601 shown in FIG. 6. A critical combination of doping density and thickness (Tₛᵢ) of the body determine whether the FET operates in a Fully Depleted (FD) mode, or a Partially Depleted (PD) mode. The embodiments described herein apply to both cases. Thicker Tₛᵢ and higher body doping place the FET in the PD mode while thin body thickness and/or low body doping result in FD operation. Asymmetric gates are also possible within current dual gate technology. An Asymmetric gate is characterized by two conductive channels of unequal strength or conductivity as illustrated in the electron density graph 701 shown in FIG. 7. The asymmetry between the front and back gate results in a difference in inversion carrier (electron for NFETs, hole for PFETs) density for the two channels with a corresponding difference in IV curves for the front and back-channel devices.

FIG. 8a illustrates the cross section of a symmetric dual gate FET and FIGS. 8b-e show cross sectional views of a number of exemplary asymmetric dual gate FET embodiments. As noted above, the symmetric structure shown in FIG. 8a is characterized by two “parallel” FETs with equivalent gate work functions and oxide thickness, as well as uniform doping in the channel region which results in equal strength or conductivity for the two transistors comprising the dual gate FET. Sufficient thickness of the channel region is required to support two distinct channels. Asymmetry in the dual gate FET may be induced through methods shown infra, either alone, or in combination to alter the threshold voltage, drive strength or carrier concentration of the front or back side device relative to its counterpart. Process parameters which may be used to modify threshold voltages or device strength include, but are not limited to, a difference in oxide thickness, doping of gate polysilicon material, or materials of differing work function for the two gate electrodes, grading of the channel doping between the two gate regions or introduction of impurities such as cesium into the gate of one of the FETs to either raise or lower local threshold voltage. These and other process parameters may be used alone or in combination to generate an intentional asymmetric behavior between the front and back gate regions of the dual gate FET. In the dual gate FET of FIG. 8a, the thickness of the front oxide 801a and back oxide 802a are equivalent and the doping density of the channel 803a is uniform. Further, the front gate 804a and back gate 805a of the device are doped equally. Accordingly, the device of FIG. 8a is a symmetric dual gate FET with two equal strength channel regions. The dual gate FET of FIG. 8b is similar to the symmetric dual gate FET of FIG. 8a, with regard to channel and gate doping, however, back oxide 802b and front oxide 802b differ in thickness resulting in an asymmetric dual gate FET. In the example of FIG. 8b, the thicker back oxide 802b creates a back channel which is weaker than the front channel associated with front oxide 801b. Variance in work function between the front gate 804b and back gate 805b of a dual gate FET may also be used to create an asymmetric dual gate FET as provided in FIG. 8c. The device of 8c features front oxide 801c and back oxide 802c of equivalent thickness and a uniformly doped channel 803c. Asymmetry is created by doping the front gate and back gate of the device in different manners or strengths, for example, the front gate 804c may be doped with P-type impurities and the back gate 805c may be doped with N-type impurities, Generating different work functions and relative strength for each of the gates.

Furthermore, dual gate FETs which are otherwise symmetric by virtue of their gate doping and oxide thickness characteristics may be made asymmetric by varying the channel region doping across their channel cross-section as illustrated in FIG. 8d. In the example device of FIG. 8d, the doping in the channel region under front gate 804d differs from the doping in the channel region under back gate 805d, creating asymmetry in the gate voltage vs. channel depletion relationship between the front channel and back channel. FIG. 8e provides another example embodiment of an asymmetric dual gate FET. The device of FIG. 8e includes gates with equivalent doping, uniform doping in the channel region and equivalent thickness in front oxide 801e and back oxide 802e. Asymmetry is generated by adding an impurity, for example Cesium, to one of the gates to imbalance the threshold voltage of one of the two channels, altering the strength of one channel relative to the other. Techniques for creating asymmetric devices in FIGS. 8b-e, while shown separately, may be practiced in combination to yield a desired asymmetric behavior. Furthermore the relative strength of the front gate need not always be greater than that of the back gate in an asymmetric device. The relative strength of the front and back devices may be switched.

Dual gate FETs may be realized using either planar techniques or FIN techniques. For planar techniques, those skilled in the art will appreciate that the structures shown in FIGS. 8a-e can be implemented on the surface of a semiconductor substrate, which may be silicon or another material. The back gate and back oxide of the device is deposited at the bottom of the device stack layers, with the source, channel and drain regions stacked above and topped with the front gate region. In regard to the FIN FET implementation, those skilled in the art will appreciate that the structures shown in FIGS. 8a-e can be implemented on a suitable semiconductor substrate. All regions of the FIN FET device are built above the substrate, with the width of the device defined as the height of the top of the gate, oxide and channel regions above the substrate and the source and drain regions rising above the substrate at either end of the channel region.

### SUMMARY OF THE INVENTION

A dual gate FET topology is disclosed for use in gate array background cell design and processes to implement design structures, wherein the channel region of a first gate and a second gate of the same device may be independently processed to produce asymmetric parametric responses, such that operating parameters, including threshold voltage, carrier concentration and drive strength for each gate may be optimized for particular circuit functions and applications. The dual gate-gate array structures may exhibit asymmetric performance characteristics with respect to each gate of the structure to accommodate system requirements or critical path timing constraints. The asymmetric channel regions may be used to construct circuit functions of multiple performance levels within the same physical area.

### BRIEF DESCRIPTION OF THE DRAWINGS

Referring to the exemplary drawings wherein like elements are numbered alike in the several Figures:

FIG. 1 illustrates the plan view of a physical layout of a prior art gate array background cell having dedicated PFET and NFET device regions that may be interconnected to realize a particular logic function.

FIGS. 2a-c illustrate the cross sectional views of prior art gate array having NFET, PFET and isolation device regions.

FIGS. 3a and 3b illustrate the schematic and physical layout, respectively of a prior art two-input AND gate implemented with two abutting gate array cells.

FIG. 4 illustrates several circuit topologies in prior art gate array cell technology for current source and diode-connected load applications.

FIG. 5 illustrates the cross sectional view of a prior art dual-gate FET device.

FIG. 6 illustrates a cross sectional view of a prior art symmetric dual gate FET device together with a graph of electron density versus position.

FIG. 7 illustrates a cross sectional view of a prior art asymmetric dual gate FET device together with a graph of electron density versus position.

FIGS. 8a-e illustrate several cross sectional views of prior art dual gate FET structures with different doping densities specified for the front and back gates producing symmetric and asymmetric gate properties.

FIGS. 9a-c illustrate cross sectional views of planar dual gate FET structures according to an exemplary embodiment for NFET, PFET and isolation device regions.

FIGS. 10a-d illustrate the cross sectional and physical layout views, respectively of NFET and PFET dual gate structures according to an exemplary FIN FET embodiment.

FIGS. 11a-c illustrate the schematic and physical layout views of a performance tuned 2-input OR gate implemented in both a planar FET and a FIN FET dual-gate structure gate array cell according to exemplary embodiments.

FIG. 11d presents an alternative FINFET physical layout of the dual-gate structure shown in FIGS. 11a-c, according to an exemplary embodiment.

FIG. 12a-c illustrate the schematic and physical layout views of a performance tuned 2-input AND gate implemented in both a planar FET and a FIN FET dual-gate structure gate array cell according to exemplary embodiments.

FIG. 12d presents an alternative FINFET physical layout of the dual-gate structure shown in FIGS. 12a-c, according to an exemplary embodiment.

FIGS. 13a-c illustrate the schematic and physical layout views of dual-gate FET current sources implemented with front gate bias, back gate bias and dual gate bias, respectively, according to exemplary embodiments.

FIGS. 14a-c illustrate the schematic and physical layout views of dual-gate FET based current loads implemented with a front gate diode, back gate diode and dual gate diode configuration, respectively, according to exemplary embodiments.

FIG. 15 illustrates a selectable current source utilizing a dual-gate FET structure with front and back gate bias.

FIG. 16 illustrates a cross sectional view of a back-gated tri-gate transistor in bulk silicon technology.

FIG. 17 illustrates a cross sectional view of the back-gated tri-gate transistor shown in FIG. 16 in silicon-on-insulator (SOI) technology.

FIG. 18 illustrates the physical layout of the SOI back-gated tri-gate transistor shown in FIG. 17.

FIG. 19 depicts a process flow diagram for gate array cell design, test, characterization and verification.

### DETAILED DESCRIPTION OF THE PREFERRED EMBODIMENTS

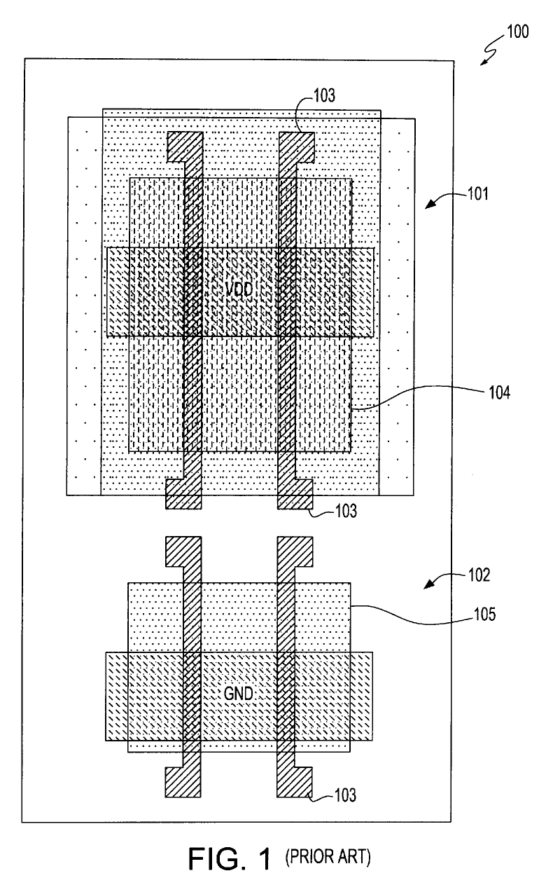

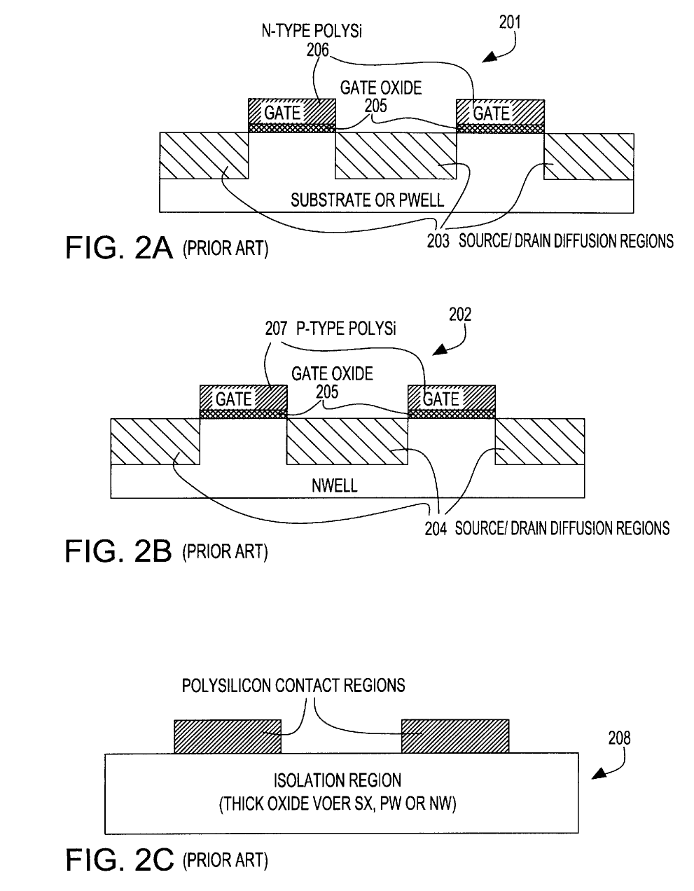

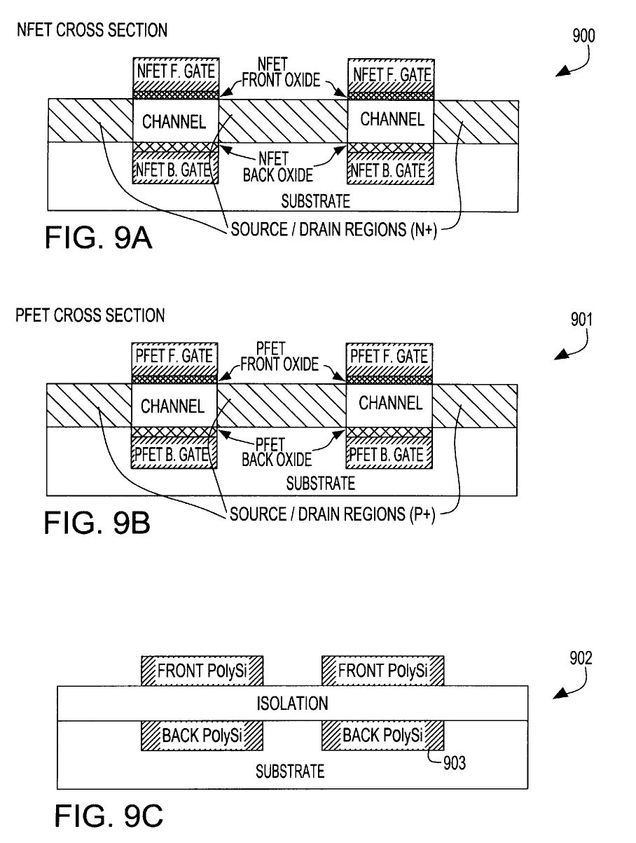

In a first aspect of the invention, a gate array cell utilizing dual gate NFET and PFET structures is presented. FIGS. 9a-c illustrate cross sections of a planar dual gate embodiment of the gate array cell which consists of two NFETs and two PFETs by example, but those skilled in the art will appreciate that many configurations with alternative FET counts are possible. The source and drain diffusion regions for the gate array cell are positioned at the far left and right of the cell in each of the PFET and NFET regions as well as in the center of the cell in the respective FET regions similar to prior art structures shown in FIGS. 1 and 2. However, the prior art surface channel FETs are replaced by dual gate FETs, which may be either symmetric or asymmetric in performance. The basic gate array cell structure is also differentiated from the prior art in that allocation is made for contacting of both the front and back gate of each transistor within the isolation regions of the cell. As illustrated in FIG. 9c, contact areas 903 for polysilicon may be extended to opposite sides of each FET. Alternatively, contact could be made through use of different lengths of PC extensions beyond the transistor region, creation of polysilicon bends or fattening at different points outside the channel region on the same side of the FET, extension of one polysilicon gate to one side of the channel region and extension of its counterpart on the opposite side of the channel region or some combination thereof.

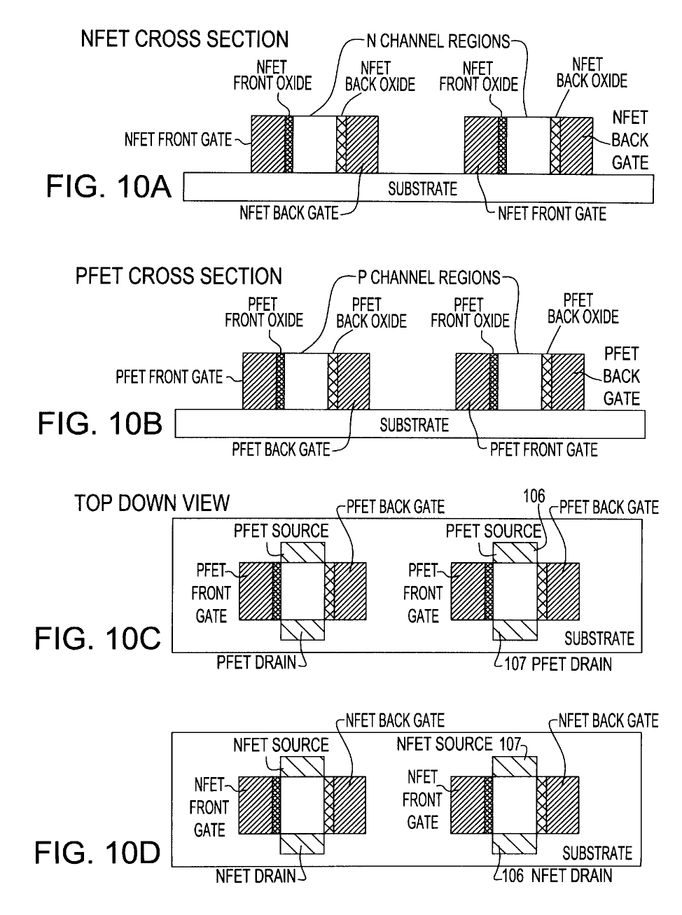

Referring now to FIGS. 10a-d, cross sectional and plan views of a FINFET embodiment for a NFET and PFET gate array cell are shown, as in the planar FET configuration shown in FIGS. 9a-c where bifurcated cells 900 and 901 consisting of two NFET and two PFET dual gate structures are illustrated. Those skilled in the art will appreciate that different FET counts are possible. Either or both the NFETs and PFETs may be defined as either symmetric or asymmetric dual gate devices. With reference to the cross section views shown in FIGS. 10a and 10b, current in the channel can be envisioned as flowing into or out of the page (i.e., source and drain areas not illustrated in the cross sectional view. The Source and Drain regions 106, 107 of the FINFET devices are clearly shown in the plan view of FIGS. 10c and 10d. Also apparent in the plan view is the inherent isolation between adjacent FETs in both the NFET and PFET regions of the gate array cell. This isolation region presents a distinct advantage of the FINFET gate array cell over planar implementations of both prior art surface FET cells and the dual gate planar cell as circuits implemented using the FINFET gate array cell will not require additional isolation devices to separate unique source/drain regions, increasing space efficiency.

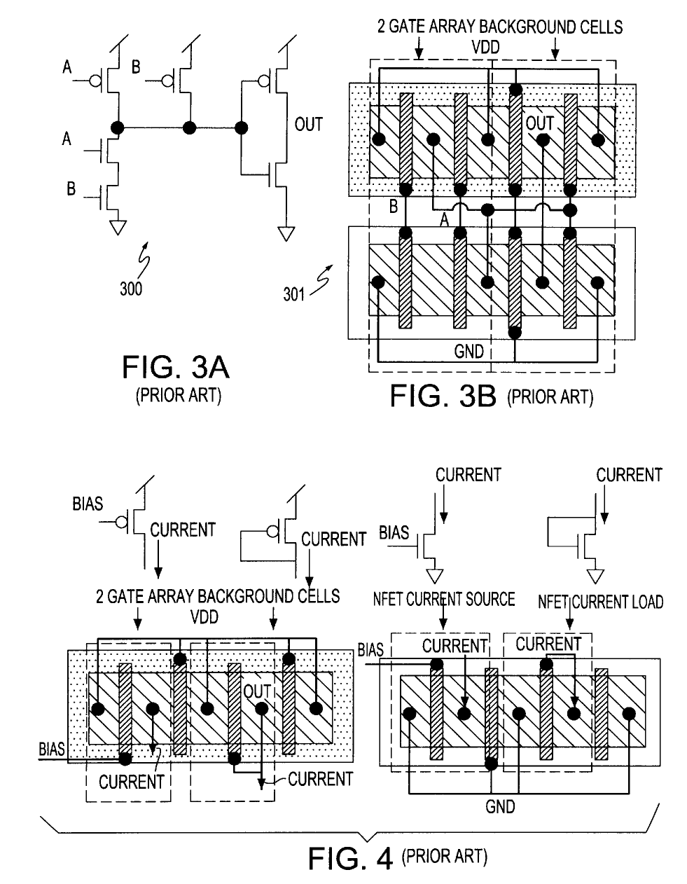

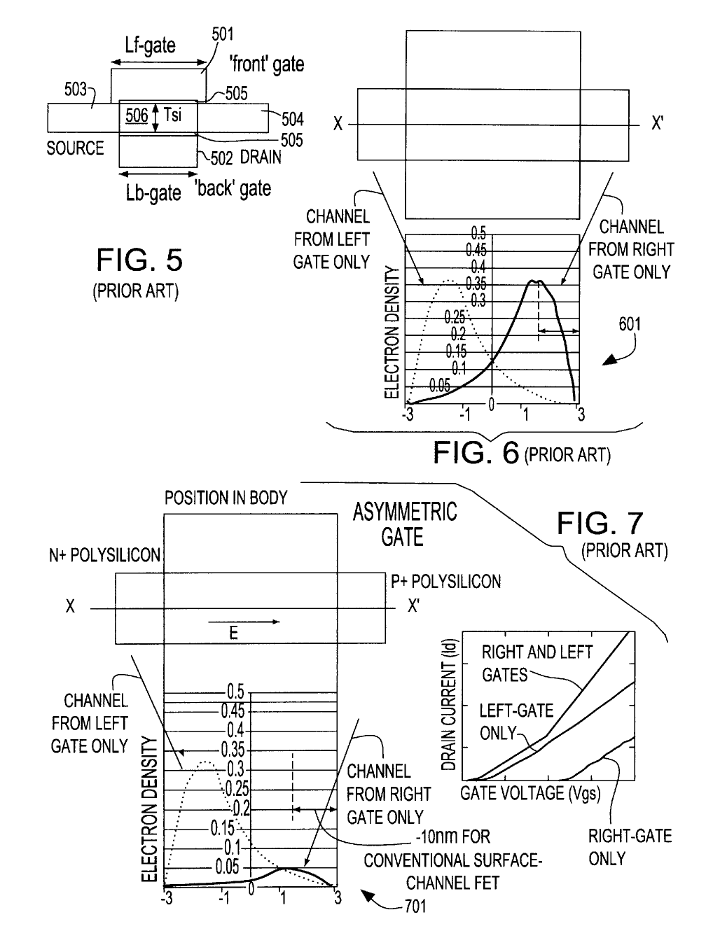

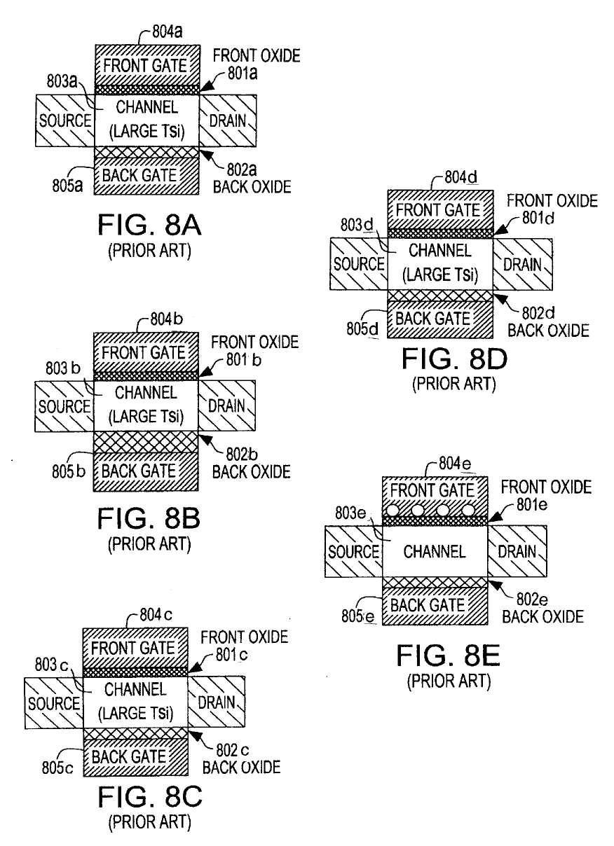

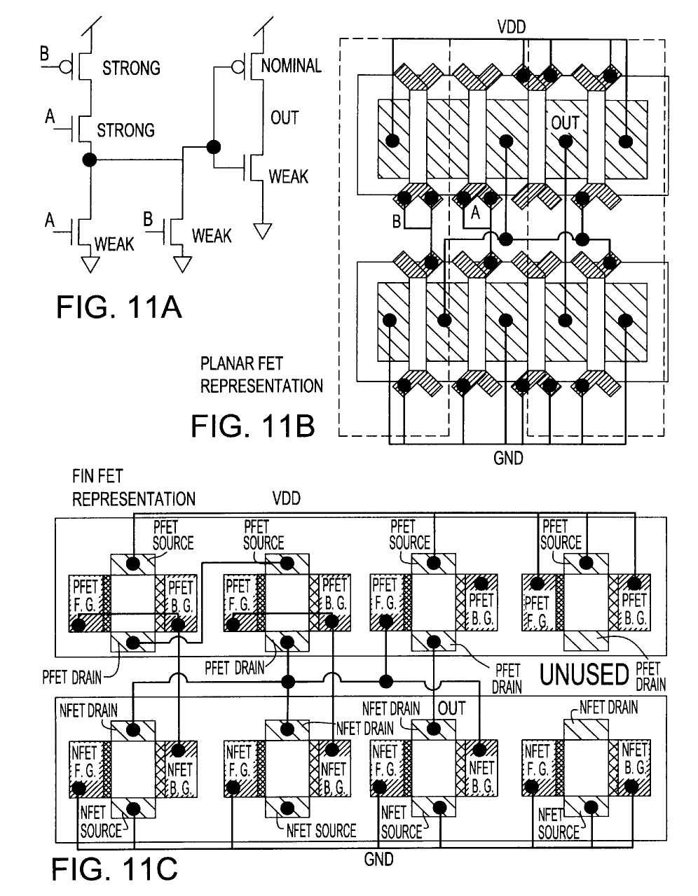

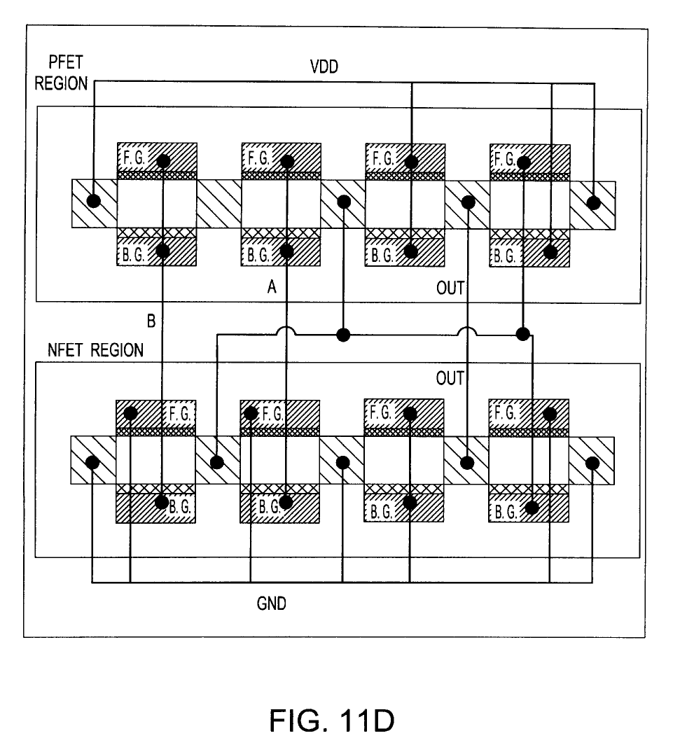

In a second aspect of the invention, methods and capabilities for implementing flexible circuit designs within dual gate-gate array background cell structures are presented. FIGS. 11a-c illustrate an exemplar gate array embodiment of a 2-input OR function using the dual gate-gate array background of FIGS. 9a-c and 10a-d. A schematic is provided along with both a planar and FIN FET physical representation. In comparison to FIG. 3, each of the FETs in the schematic may take on two or three different performance or conductivity levels without changing the physical size of the circuit, depending on whether the base dual gate FET is processed with a symmetric or asymmetric gate channel region. In a symmetric embodiment, the FET may be wired as a single strength device using only one of the two available channels, or double strength with both of the channels wired. In an asymmetric embodiment, the FET may be wired for a first strength where only the front channel is used; a second strength where only the back channel is used; and a third strength where both the back and front channels are used. FIG. 11a illustrates a potential asymmetric configuration of dual gate FETs to implement the 2-input OR function with a combination of weak, nominal and strong devices in two of the new gate array background cells. Implemented in a prior art gate array with one finger defined as a weak device, two defined as nominal, and three defined as strong, the circuit would consume five cells. Referring to the planar FET layout portion of FIG. 11b, each dual gate FET is illustrated as the solid region overlaying the dotted pattern diffusion area. Hatched regions of each FET illustrate connection points over isolation for the stronger of the front or back gates while the (light) checkered region illustrates the connection points over isolation for the weaker of the front and back gates in the dual gate FET. Weak FETs are created by wiring up only the weaker gate to the input signal while the stronger gate is disabled by tying it to the appropriate power rail depending on whether it is a NFET or PFET. Nominal FETs reverse the signal and disabling connections of the weak gate and strong FETs are created connecting both the strong and weak gates of the dual gate device to the input signal. Interconnect routing lines in FIGS. 11b and 11c show the gate and diffusion connectivity to implement the function with the performance metric stipulated in the schematic, i.e.: weak, nominal strong. The new dual gate array cell allows for many performance permutations of a single function to be implemented within the same gate array area. The dual gate structure of FIG. 11b allows implementation of the schematic circuit of FIG. 11a in 2-cells versus the 5-cell usage in the prior art. Referring to 11c, the FINFET implementation of the circuit is similar to the planar version of FIG. 11b, although it consumes two fewer FETs as source and drain diffusion isolation is inherent to the layout illustrated. With a gate array cell definition of 4 FETs (2 NFETs and 2 PFETs) the FIN FET implementation of FIG. 11c is implemented in two cells or 8 FETs. If the cell was redefined to be 2 FETs (1 NFET and 1 PFET), one transistor pair could be saved for other logic functions. If the FETs were rotated 90 degrees and shared source/drain diffusions, the connectivity would match that of the planar design (see FIG. 11d). As with the planar implementation of FIG. 11b, isolation FETs would be required and the schematic circuit implementation would require 2-4 FET cells or 8 transistors.

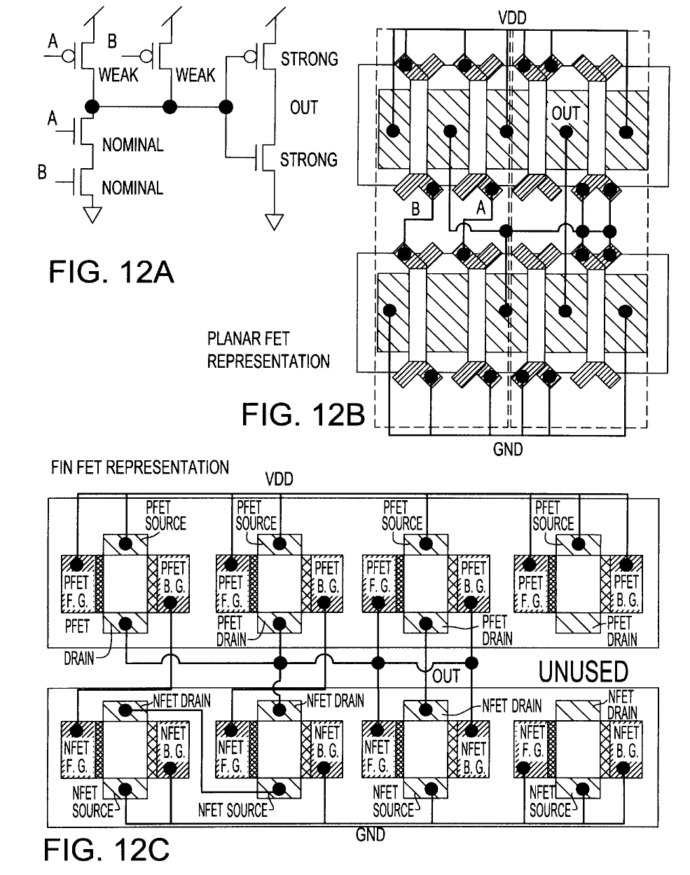

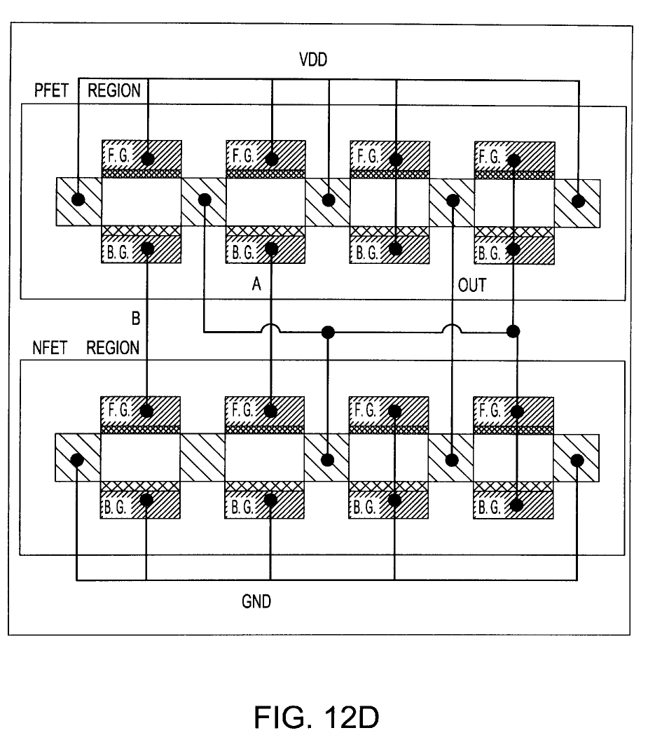

FIGS. 12a-c illustrate a second circuit schematic and physical layout embodiment implemented within the new gate array cell. Using the weak, nominal or strong definitions for the cell as described for FIGS. 11 a-c, the OR function shown consumes four cells in the prior art gate array, but only two cells with the new background topology. Similar to FIG. 11c, the FINFET physical representation shown in FIG. 12c, eliminates two additional FETs by redefining the gate array cell to a single NFET and a single PFET. Alternatively, the FINFETs may be rotated 90 degrees such that their source and drain connections may be shared, and the physical implementation and isolation requirements shown in FIG. 12d would be similar to the planar implementation shown (see FIG. 12b).

Performance tuning capability available with the new gate array library cell incorporating the dual gate FET is not limited to powering up or down all devices of a single function type, such as NFET or PFET stacks by the same amount. The new gate array cell makes in not only possible, but reasonable to skew performance of one FET in a stack versus another to slow one logic path in relation to another, reducing or eliminating any possible divergence in pin-dependent delays in a logic path within an IC.

Those skilled in the art will appreciate that trebling of performance selectivity taught for gate array implementations is not exclusive to gate array. Similarly, use of dual gate transistors in standard cell circuit designs where FETs are more particularly sized could be made to have several different performance offerings within the same circuit area and pinout utilizing the library techniques discussed above. Double gate standard cell designs can also provide a means of altering the performance of a standard cell circuit after FEOL processing is complete, with alteration of BEOL masks only, similar to gate array circuits.

An additional degree of selectivity may be realized when either gate array or standard cell circuits are built with dual gate devices and devices of either type are left unused, in that it may be possible to implement certain logic changes to existing logic using only the available extra channels in the dual gate devices. A first example of logic transformation is within FETs used as pass-thru gates where an unused gate/channel can be used to add a new pass gate control such that a logic value is propagated from source to drain when either the first or second gate is enabled. A second example of logic transformation is within primitive logic functions where unused front or back gates may be used to transform a primitive logic function into a more complex partially-defined custom AND-OR or OR-AND function. Those skilled in the art would recognize the ability to use extra single gates/channels to modify circuit functionality in many ways.

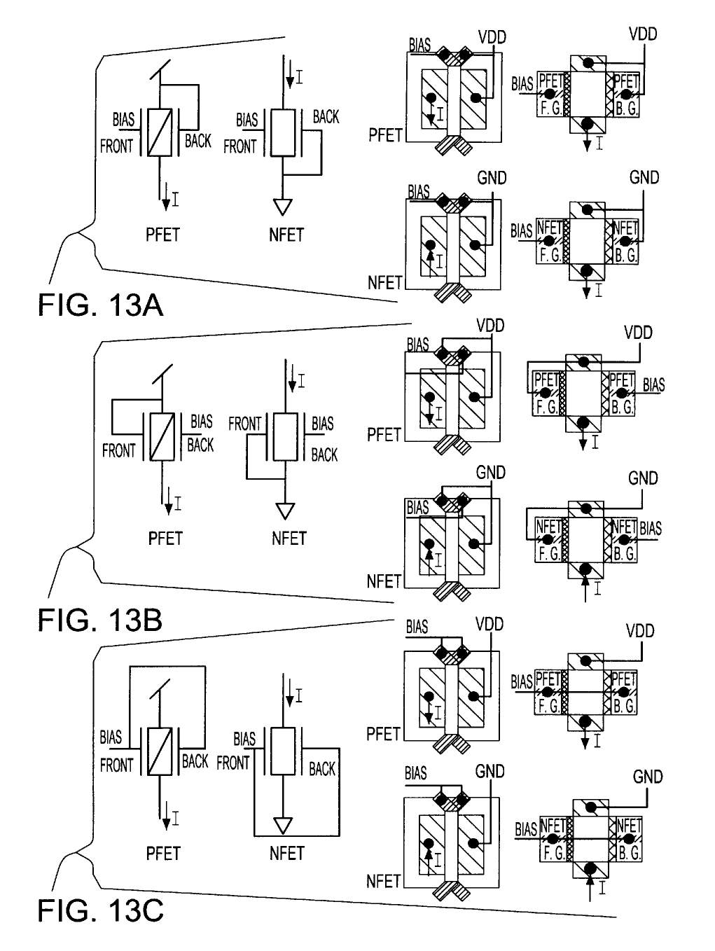

While FIGS. 11a-c and 12a-c teach gate array logic design with the new gate array cell, flexibility in analog use of dual gate FETs is also possible. FIGS. 13a-c and 14a-c illustrate a variety of current sources and diode-connected load FETs that can be created using a single dual gate FET to implement a current source or load device with asymmetric performance characteristics. In FIG. 13a, a front gate biased current source is shown for both PFET and NFET implementations. The current sources shown in FIG. 13a are constructed with an asymmetric dual gate device where the front gate is connected to a known bias and a back gate and source of the device are tied to the power supply rail as appropriate with a current proportional to the drive strength of the front gate of the FET provided at the drain. In FIG. 13b, a second pair of current sources is shown wherein the front gate is biased to the power rail of the PFET or NFET and the back gate is wired to a known bias and a drive current provided at the drain proportional to the strength of the back gate. In FIG. 13c, a third pair of current sources is shown in which both front and back gates are biased with the same voltage. The source is connected to either the corresponding power rail for the PFET or NFET device with current proportional to the sum of the strengths of the back and front gate provided at the drain. If the dual gate device exhibits symmetric behavior, two current values can be realized; a current source using only one of two symmetric front and back gates and a current source utilizing both the front and back gates in parallel. If the dual gate device exhibits asymmetric behavior, three current values can be realized; a first current source proportional to the strength of the front gate only, a second current source proportional to the strength of the back gate only and a third current source proportional to the summation of front and back gate strengths. Using the dual gate structure, whether the device is symmetric or asymmetric, all current production possibilities can be implemented in the same device area, unlike the prior art. Along with the schematic representations for each of the possible sources provided in FIG. 13a-c, physical depictions of each of the devices is provided for both the planar and FIN FET dual gate device technologies.

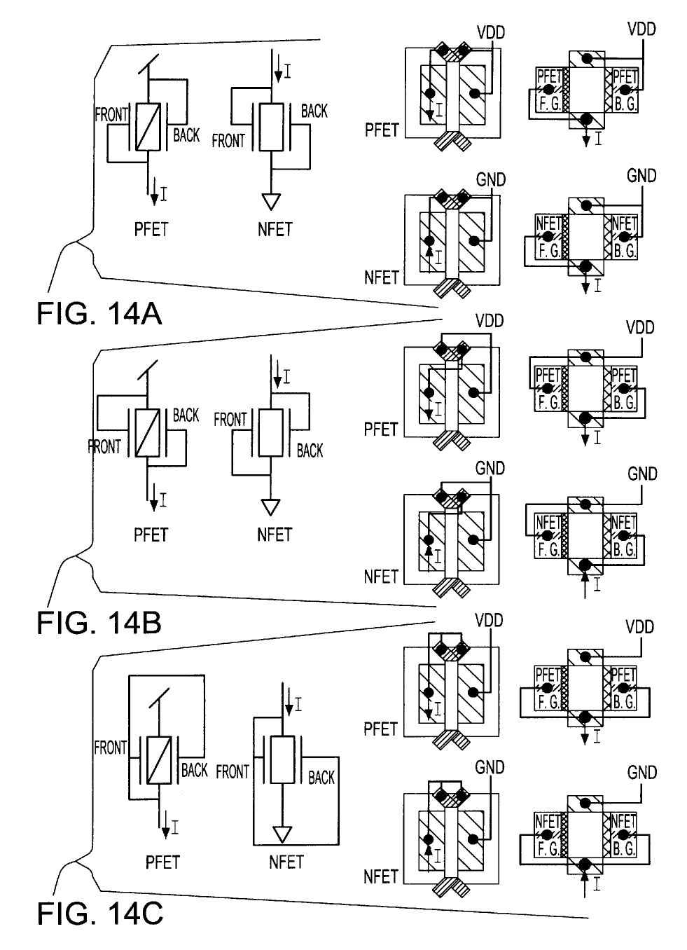

Similar in schematic and physical form, FIGS. 14a-c illustrate three types of diode-connected FET loads constructed from a single asymmetric dual gate FET. For a symmetric FET implementation, the number of possibilities is reduced to two. The diode structures differ from the current sources detailed in FIG. 13a-c in that the channel or channels through which conduction is desired have their gate wired to the drain of the device instead of an external bias. Again, the dual gate FET yields possibilities not possible in prior art in that a single device can implement three different strengths within the same unit cell circuit area.

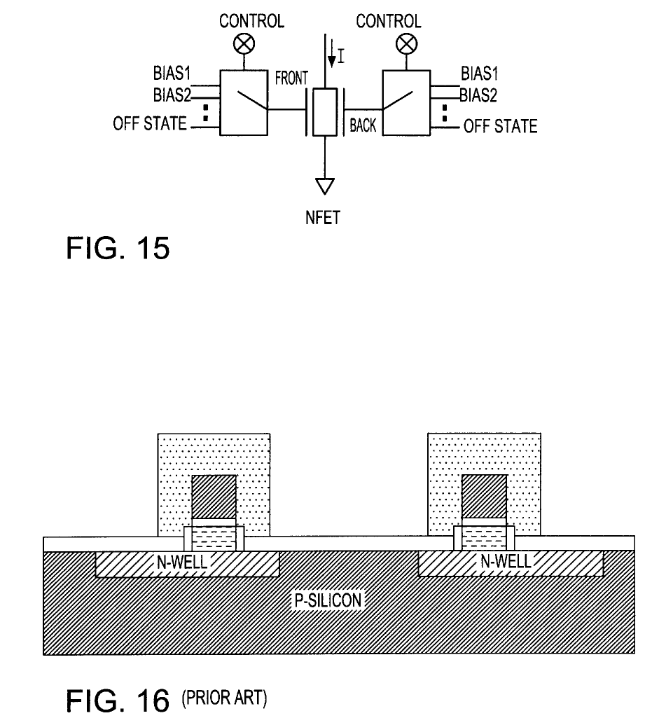

As an extension to the multiple strength current sources and current loads of FIGS. 13a-c and 14a-c, the connectivity of the front and back gates of the dual gate FET may be made selectable such that control bits or lines can alter the bias point, connectivity or on/off state of the front and back gates separately to implement a number of programmable current sources and loads. A schematic embodiment of this extension is shown in FIG. 15. This embodiment, while illustrated for use in a current source or load, may also be useful in allowing programming of logic circuit strengths in FPGA, ASIC or custom circuits to enable design tradeoffs between power and performance while implementing the function using the same set of circuit macros.

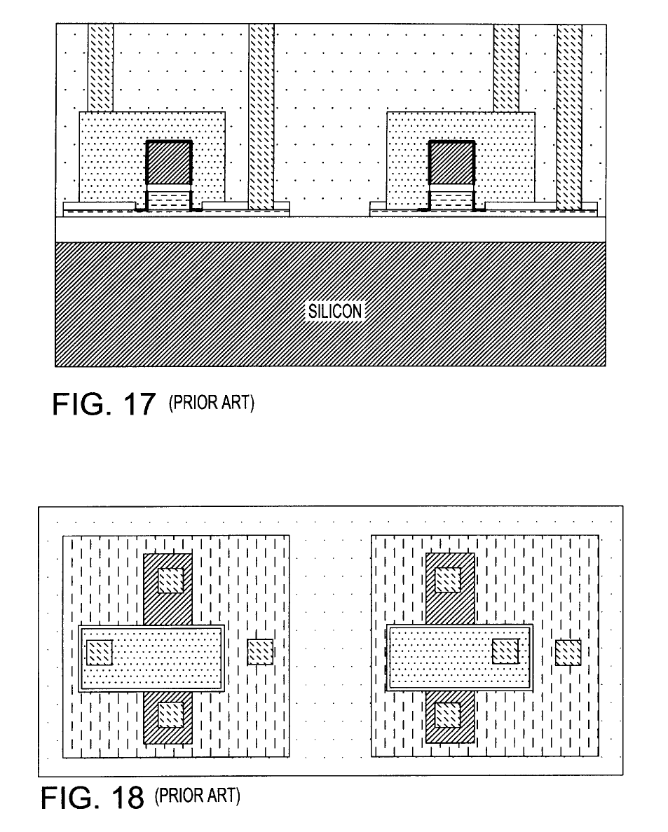

U.S. patent application Ser. No. 11/160,361 entitled “Subtrate Backgate for Tri-Gate FET,” filed on Jun. 21, 2005, incorporated herein by reference, teaches a new transistor structure using the back-gated tri-gate transistor, shown in FIGS. 16-18. The gate electrode shown in dotted relief wraps around three sides of a silicon ‘fin’, and all three sides have thin gate dielectric separating the gate electrode from the body. Typically the body aspect ratio (height:width) is between 2:1 and 1:2 to allow acceptable short-channel behavior in terms of leakage and threshold voltage. The bottom electrode, below the body, is either a well in bulk silicon brought in close proximity to the body (FIG. 16) or a gate electrode isolated from the substrate wafer by an insulator or buried oxide (BOX) (FIG. 17). Those skilled in the art will recognize that the structures shown in FIGS. 16-18 can be substituted in the above described dual-gate applications as an alternate embodiment.

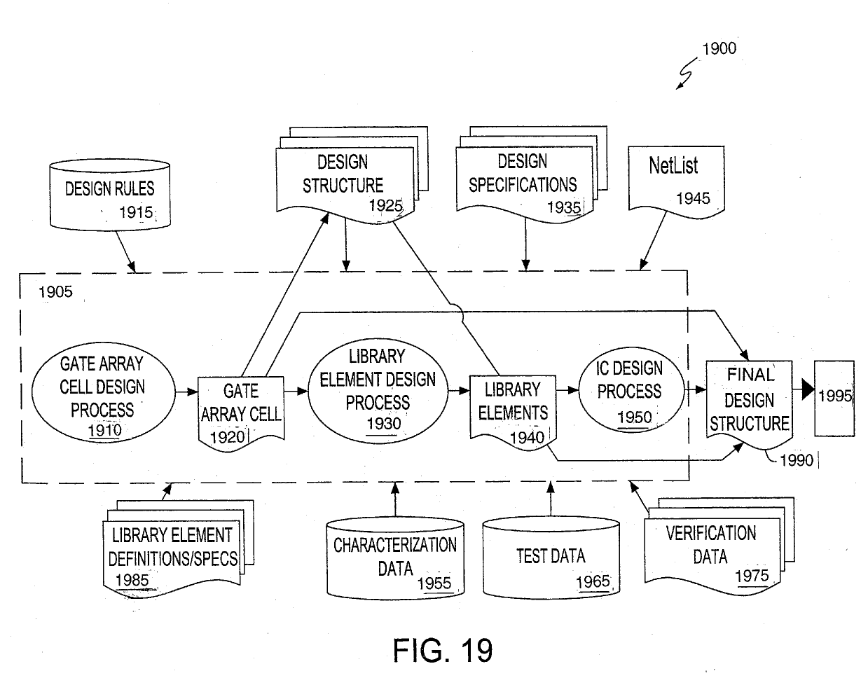

Also disclosed are embodiments of a design structure embodied in a machine readable medium used in a design flow process, where the design structure represents the gate array cell and/or logical circuit functions implemented with the gate array cell discussed in detail above and illustrated in FIGS. 9 through 16. More specifically, FIG. 19 shows a block diagram of an example design flow 1900. Design flow 1900 may vary depending on the gate array cell, logical circuit library and/or integrated circuit (IC) chip being designed. For example, design flow 1900 may vary depending on the technology chosen for implementation of the gate array cell and logical circuit library or the technique for implementation of gate asymmetry. Design flow 1900 may comprise sub-processes 1910 for designing a gate array background cell utilizing design rules 1915 which describes the technology, design specifications 1935 which describes the requirements for the gate array cell which may include FET count, FET performance and/or FET symmetric/asymmetric characteristics, technology characterization data 1955 as well as other input files. Process 1910 generates gate array background cell 1920 which for example may be designed to provide symmetric or asymmetric front gate/back gate performance. Gate array background cell 1920 becomes part of Design structure 1925 enabling hierarchical design of logical circuit functions in process 1930. In block 1930 a library of logical circuit functions is for example, designed based on design specifications 1935, library element definitions 1985 and characterization data 1955 as well as gate array cell 1920 and design structure 1925. In a similar manner, library elements 1940 generated in process 1930 may become part of design structure 1925 and may be integrated with netlist data 1945, verification data 1975, test data 1965, characterization data 1955, design specifications 1935 and design rules 1915 as well as other data to generate a more complex logical circuit function or IC.

Design structure 1925 may incorporate the gate array background cell 1920 as well as library elements 1940 described as one or more of mask layout data (GDS), schematic data and high level or symbolic descriptions. Design structure 1925 may be stored in one or more machine readable mediums. For example design structure 1925 may be a text file or a graphical representation

Design process 1900 further includes, for example, standard circuit design processes such as timing analysis, verification tools, design rule checkers, place and route tools, etc. One of ordinary skill in the art of integrated circuit design can appreciate the extent of possible electronic design automation tools and applications used in design process 1905 without deviating from the scope and spirit of the invention.

Ultimately design process 1900 translates design requirements for a gate array cell as well as logical function circuit and integrated circuit design embodiments (if applicable) into final design structure 1990 (e.g., information stored in a GDS storage medium). Final design structure 1990 may comprise information such as, for example, test data files, design content files, manufacturing data, layout parameters, wires, levels of metal, vias, shapes, test data, data for routing through the manufacturing line, and any other data required by a semiconductor manufacturer to produce the gate array cell logical circuit functions/ICs derived from the gate array cell as disclosed herein. Final design structure 1990 may then proceed to a stage 1995 of design flow 1900; where stage 1995 is, for example, where final design structure 1990: proceeds to tape-out, is released to manufacturing, is sent to another design house or is sent back to the customer.

The dual gate FET topology disclosed provides a basis for integrated circuit design which bridges the divide between prior art standard cell (SC) and gate array (GA) designs; providing performance tailoring and performance vs. physical size independence of the former with the physical uniformity and design/manufacturing speed of the latter. While prior-art gate array topologies offered tuning only on a per-transistor or per-cell basis, the topology disclosed further teaches tuning below the unit transistor level treating each channel within a single dual gate FET device separately to create multiple performance levels of a logic function within a fixed physical area. In order to facilitate selective use of either or both of the front gate and back gate devices, a structure is provided which allows independent and selective connection of one or both gates, a requirement that would not be apparent to a circuit designer implementing either prior art gate array or standard cell circuits.

While both design and manufacture of prior-art SC and GA topologies was performed in a manner to minimize asymmetry between devices in order to maximize yield, the new dual gate FET topology disclosed leverages asymmetry between a front and back gate on one or more FET types within the IC to substantially increase the number of library element permutations possible within a unit area.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A method of implementing a gate array cell within an integrated circuit, comprising:
providing a first dual gate device in a PFET region of the gate array cell;
providing a second dual gate device in an NFET region of the gate array cell;
selecting device parameters of a first channel region of the first dual gate device for a first performance level;
selecting device parameters of a second channel region of the first dual gate device for a second performance level;
selecting device parameters for a first channel region of the second dual gate device for a first performance level; and
selecting device parameters for a second channel region of the second dual gate device for a second performance level;

2. The method according to claim 1, further comprising selecting manufacturing process parameters for the first and second channel regions of at least one dual gate device such that the first and second channel regions of the at least one dual gate device exhibit symmetrical performance characteristics.

3. The method according to claim 1, further comprising selecting manufacturing process parameters for the first and second channel regions of at least one dual gate device such that the first and second channel regions of the at least one dual gate device exhibit asymmetric performance characteristics.

4. The method according to claim 3 further comprising varying a gate oxide thickness of at least one dual gate device to realize asymmetric performance characteristics.

5. The method according to claim 3, wherein the manufacturing process parameter comprises varying a gate work function to realize asymmetric performance characteristics for the at least one dual gate device.

6. The method according to claim 3, wherein the manufacturing process parameter comprises asymmetrically doping the first and second channel regions to realize asymmetric performance characteristics of the at least one dual gate device.

7. The method according to claim 3, wherein the manufacturing process parameter comprises adding an unequal distribution of impurities to a first and second gate region of the at least one dual gate device.

8. The method according to claim 1, wherein the gate array cell further comprises a primary library element of a mask programmable gate array integrated circuit.

9. The method according to claim 1, further comprising providing a filler cell adapted to facilitate logic changes in a standard cell design methodology through modification of interconnect lithography mask layers.

10. The method according to claim 1, further comprising instantiating a plurality of gate array cells in an integrated circuit to facilitate logic repair through modification of interconnect lithography mask layers of the integrated circuit.

11. The method according to claim 1, further comprises dual gate devices implemented with a FIN FET manufacturing process technology.

12. The method according to claim 1, wherein the gate array cell further comprises dual gate devices implemented with planar FET manufacturing process technology.

13. The method according to claim 1, wherein the gate array cell further comprises dual gate devices implemented with tri-gate devices.

14. A gate array cell, comprising:
a first dual gate device instantiated within a PFET region of the gate array cell;
a second dual gate device instantiated within an NFET region of the gate array cell;
a first channel region of the first dual gate device with process parameters selected for a first performance level;
a second channel region of the first dual gate device with process parameters selected for a second performance level;
a first channel region of the second dual gate device with process parameters selected for a first performance level; and
a second channel region of the second dual gate device with process parameters selected for a second performance level.

15. The gate array cell according to claim 14 further comprising dual gate devices implemented with FIN FET manufacturing process technology.

16. The gate array cell according to claim 14 further comprising dual gate devices implemented with planar FET manufacturing process technology.

17. The gate array cell according to claim 14 further comprising dual gate devices implemented with back gated tri-gate transistors.

18. The gate array cell according to claim 14, wherein the plurality of gate array cells are interconnected through physical abutment.

19. The gate array cell according to claim 14, wherein at least one gate array cell is instantiated as a filler cell capable of facilitating logic changes in a standard cell design methodology through modification of interconnect lithography mask layers.

20. The gate array cell according to claim 14, wherein at least one of a plurality of polysilicon gate structures is extended to facilitate connectivity with adjoining gate array cells through interconnect lithography mask layers.

21. The gate array cell according to claim 14, wherein both a front and a back gate of each transistor may be contacted within an isolation region of the cell.

22. The gate array cell according to claim 14, wherein each of the first and second gate regions of the first dual gate device and the second dual gate device may be biased individually or in combination.

23. A gate array cell according to claim 14 further comprising at least one asymmetric dual gate FET

24. A gate array cell according to claim 14 further comprising at least one symmetric dual gate FET.

25. A design structure embodied in a machine readable medium used in a design process, the design structure comprising:
a first dual gate device instantiated within a PFET region of the gate array cell;
a second dual gate device instantiated within an NFET region of the gate array cell;
a first channel region of the first dual gate device with process parameters selected for a first performance level;
a second channel region of the first dual gate device with process parameters selected for a second performance level;
a first channel region of the second dual gate device with process parameters selected for a first performance level; and
a second channel region of the second dual gate device with process parameters selected for a second performance level.

26. The design structure according to claim 25, wherein the first and second channel regions of at least one dual gate device exhibit symmetrical performance characteristics.

27. The design structure according to claim 25, wherein the first and second channel regions of at least one dual gate device exhibit asymmetric performance characteristics.

28. The design structure according to claim 25, wherein multiple channels within a dual gate device are utilized to implement a circuit function with a selectable drive strength.

29. The design structure according to claim 25, wherein a logical function is implemented.

30. The integrated circuit function according to claim 25, wherein a current source is implemented.

31. The design structure according to claim 25, wherein a current load is implemented.

32. The design structure according to claim 25, wherein a plurality of gate array cells are instantiated in an integrated circuit to facilitate logic repair through modification of interconnect lithography mask layers of the integrated circuit.

33. The design structure according to claim 25, further comprising an oxide based asymmetric dual gate FET having a first gate with a first gate oxide thickness and a second gate with a second gate oxide thickness to realize a different threshold voltage and drive strength as between the a first gate and a second gate of the dual gate FET.

34. The design structure according to claim 25, further comprising a work function based asymmetric dual gate FET, wherein a first gate is doped with a first level of impurities and a second gate is doped with a second level of impurities to realize a threshold voltage and drive strength differential as between a first gate and a second gate of the dual gate FET

35. The design structure according to claim 25, further comprising a channel doping based asymmetric dual gate FET having a channel region with non-uniform doping to realize a different threshold voltage and drive strength as between a first gate and a second gate of the dual gate FET.

36. The design structure according to claim 25, further comprising asymmetrically doped gate structures of the dual gate FET, wherein additional impurities are implanted in a first gate to realize a different threshold voltage and drive strength as between the first gate oxide and a second gate of the dual gate FET.
